(19) United States
(12) Patent Application Publication
(10) Pub. No.: US 2024/0381572 A1
(43) Pub. Date: Nov. 14, 2024

(54) METHODS AND SYSTEMS FOR A FILTRATION ASSEMBLY FOR A COOLING SYSTEM

(71) Applicant: Hoffman Enclosures Inc., Anoka, MN (US)

(72) Inventors: Scott Stammer, Champlin, OH (US); Richard Raisanen, Coon Rapids, MN (US); Patrick McCarthy, Columbia Heights, MN (US); Matthew R. Archibald, Derry, NH (US); Peter Schrodin, Erlenbach bei Kandel (DE)

(21) Appl. No.: 18/660,912

(22) Filed: May 10, 2024

Related U.S. Application Data
(60) Provisional application No. 63/501,378, filed on May 10, 2023.

(51) Int. Cl. H05K 7/20; B01D 35/143; B01D 35/147; B01D 37/04

(52) U.S. Cl. CPC H05K 7/20272; B01D 35/143; B01D 35/147; B01D 37/046; B01D 2201/54

(57) ABSTRACT

Embodiments of the disclosure provide a filtration assembly. The filtration assembly includes a fluid inlet, a fluid outlet, first and second flow lines positioned fluidly between the fluid inlet and the fluid outlet, a differential pressure sensor, and a controller. The first flow line includes a first canister filter, a first filter housing, and a first valve configured to move between a closed position and an open position. The second flow line includes a second canister filter, a second filter housing, and a second valve configured to move between a closed position and an open position. The controller is configured to receive, from the differential pressure sensor, a differential pressure value, and when the differential pressure value is greater than a threshold value, generate a signal to one of the first and second valves to close the respective valve.

### CROSS-REFERENCE TO RELATED APPLICATIONS

This application claims priority to U.S. Provisional Patent Application No. 63/501,378, filed May 10, 2023, titled “Filter Assembly for a Cooling System,” the entirety of which is incorporated herein by reference.

### BACKGROUND

In some closed-loop liquid cooling system applications liquid is pumped through the system to remove heat from systems that include heat producing components. A liquid filter housed within a liquid filter assembly can be used in these cooling system applications to filter out any unwanted impurities from the liquid. Occasionally, the liquid filter assembly should be accessed to inspect or replace the liquid filter.

### SUMMARY

Some embodiments of the disclosure provide a filtration assembly for a liquid cooling system, including, a fluid inlet, a fluid outlet, a first flow line, a second flow line, a differential pressure sensor, and a controller. The first flow line can be positioned fluidly between the fluid inlet and the fluid outlet. The first flow line can include a first canister filter, a first filter housing, and a first valve configured to move between a closed position and an open position. When the first valve is in the closed position a fluid flow through the first flow line can be stopped. The second flow line can be positioned fluidly between the fluid inlet and the fluid outlet. The second flow line can include a second cannister filter and a second filter housing and a second valve configured to move between a closed position and an open position. When the second valve is in the closed position a fluid flow through the second flow line can be stopped. The controller can be in communication with the differential pressure sensor and the first valve. The controller can be configured to receive, from the differential pressure sensor, a differential pressure value, and when the differential pressure value is greater than a threshold value, generate a signal to one of the first and second valves to close the valve.

In some examples, the first flow line can further comprise a first air bleed valve, and the second flow line can further comprise a second air bleed valve.

In some examples, the first flow line can include a first drain port.

In some examples, the filtration assembly can include a drain valve in fluid communication with the first drain port.

In some examples, the first flow line can further include a third valve, wherein the third valve may be downstream of the first canister filter and the first filter housing and the first valve may be upstream of the first canister filter and the first filter housing.

In some examples, the filtration assembly can further include a control panel associated with the first flow line. The control panel may include a first control in communication with the controller. The controller may be further configured to provide a signal to move both of the first and third valves to a closed position in response to a first signal received from the first control.

In some examples, the controller can be further configured to receive a second signal from the first control. In response to receiving the second signal, the controller can provide an open signal to the first valve to move the first valve to the open position. The controller can wait for a predetermined period of time after providing the open signal to the first valve. After the predetermined period of time has elapsed, the controller can provide an open signal to the second valve to move the second valve to the open position.

In some examples, the control panel can include a first visual indicator configured to illuminate when the first valve and the third valve are in the open position.

In some examples, the filtration assembly can further comprise a second differential pressure sensor. The differential pressure sensor may be configured to measure a differential pressure along the first flow line, and the second differential pressure sensor may be configured to measure a differential pressure along the second flow line.

In some examples, the first filter can include a first air bleed valve.

Some embodiments of the disclosure provide a method of operating a filtration assembly, including, providing a unified fluid inlet and a unified fluid outlet, providing a first flow line downstream of the unified fluid inlet and upstream of the unified fluid outlet, providing a second flow line downstream of the unified fluid inlet and upstream of the unified fluid outlet, providing a differential pressure sensor, receiving a differential pressure measurement from the differential pressure sensor. The first flow line can include a first entry valve, a first exit valve, and a filter fluidly between the first entry valve and the first exit valve. The second flow line can include a second entry valve, a second exit valve, and a second filter fluidly between the first entry valve and the first exit valve. The differential pressure sensor can be configured to measure a differential pressure along the first flow line. When the differential pressure measurement exceeds a pressure threshold, close the first entry valve and the first exit valve.

In some examples, the method can further include receiving a servicing signal indicating an initiation of a servicing for the first filter, and in response to receiving the servicing signal, closing both of the first entry valve and the first exit valve.

In some examples, the method can further include providing a first control panel having a first button. The servicing signal can be generated upon a user engagement of the first button.

In some examples, the method can further include receiving an integration signal. In response to receiving the integration signal, the method can include opening the first entry valve, waiting for a predetermined time interval from the opening of the first entry valve, bleeding an air from the first flow line, and after the predetermined time interval, opening the first exit valve.

Some embodiments of the disclosure provide a filtration assembly comprising a fluid inlet, a fluid outlet, a first flow line, a second flow line, a differential pressure sensor, and a controller. The first flow line can be positioned fluidly downstream of the fluid inlet and upstream of the fluid outlet. The first flow line may comprise a first entry valve, a first exit valve, a first drain port, a first filter housing, and a first filter, the first drain port, first filter housing, and first filter being downstream of the first entry valve and upstream of the first exit valve. The second flow line can be positioned fluidly downstream of the fluid inlet and upstream of the fluid outlet. The second flow line may comprise a second entry valve, a second exit valve, a second drain port, a second filter housing, and a second filter, the second drain port, second filter housing, and second filter being downstream of the first entry valve and upstream of the first exit valve. The controller may be in electrical communication the first entry valve, first exit valve, second entry valve, second exit valve. The controller can include a processor. The processor can be configured to receive, from the differential pressure sensor a differential pressure measurement of a differential pressure across the first flow line. When the differential pressure measurement exceeds a threshold value, issue a signal to the first entry valve and the first exit valve to close the first entry valve and the first exit valve.

In some examples, the filtration assembly can further comprise a first control panel having a first button and a first visual indicator. The processor is further configured to receive a first signal indicative of an engagement of the first button, and in response to receiving the first signal, close the first entry valve and the first exit valve, activate the first visual indicator.

In some examples, the first control panel can include a second visual indicator wherein the processor is further configured to receive, from the first button, a second signal, open the first entry valve, wait for a predetermined period of time after opening the first entry valve, after waiting for the predetermined period of time, open the first exit valve, deactivate the first visual indicator, activate the second visual indicator.

In some examples, the first filter can include a first air-bleed valve.

In some examples, the first filter can be secured to the first filter housing with a first clamp.

In some examples, the first control panel may be secured to the first filter housing.

In some implementations, devices or systems disclosed herein can be utilized, manufactured, installed, etc. using methods embodying aspects of the disclosure. Correspondingly, any description herein of particular features, capabilities, or intended purposes of a device or system is generally intended to include disclosure of a method of using such devices for the intended purposes, of a method of otherwise implementing such capabilities, of a method of manufacturing relevant components of such a device or system (or the device or system as a whole), and of a method of installing disclosed (or otherwise known) components to support such purposes or capabilities. Similarly, unless otherwise indicated or limited, discussion herein of any method of manufacturing or using for a particular device or system, including installing the device or system, is intended to inherently include disclosure, as embodiments of the disclosure, of the utilized features and implemented capabilities of such device or system.

### BRIEF DESCRIPTION OF THE DRAWINGS

The accompanying drawings, which are incorporated in and form a part of this specification, illustrate embodiments of the disclosure and, together with the description, serve to explain the principles of embodiments of the disclosure:

FIG. 1 is an isometric view of a filtration assembly according to some aspects of the disclosure;

FIG. 2 is an isometric view of another example of a filtration assembly according to some aspects of the disclosure;

FIG. 3 is an isometric view of another example of a filtration assembly according to some aspects of the disclosure;

FIG. 4 is an exploded partial view of the filtration assembly of FIG. 3;

FIG. 5 is a partial view of a filtration assembly according to some aspects of the disclosure;

FIG. 6 is a plumbing schematic of a filtration assembly according to an embodiment;

FIG. 7 is a controls schematic of a filtration assembly, according to some aspects of the disclosure;

FIG. 8 is a flow chart of a method of servicing a filtration assembly;

FIG. 9 is a flow chart of a method of integrating a filtration assembly; and

FIG. 10 is a flow chart of a process for implementing operating modes of a filtration assembly.

### DETAILED DESCRIPTION

Before any embodiments of the disclosure are explained in detail, it is to be understood that the disclosure is not limited in its application to the details of construction and the arrangement of components set forth in the following description or illustrated in the following drawings. The disclosure is capable of other embodiments and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings. Further, “connected” and “coupled” are not restricted to physical or mechanical connections or couplings.

Also as used herein, unless otherwise limited or defined, “or” indicates a non-exclusive list of components or operations that can be present in any variety of combinations, rather than an exclusive list of components that can be present only as alternatives to each other. For example, a list of “A, B, or C” indicates options of: A; B; C; A and B; A and C; B and C; and A, B, and C. Correspondingly, the term “or” as used herein is intended to indicate exclusive alternatives only when preceded by terms of exclusivity, such as “either,” “one of,” “only one of,” or “exactly one of.” For example, a list of “one of A, B, or C” indicates options of: A, but not B and C; B, but not A and C; and C, but not A and B. A list preceded by “one or more” (and variations thereon) and including “or” to separate listed elements indicates options of one or more of any or all of the listed elements. For example, the phrases “one or more of A, B, or C” and “at least one of A, B, or C” indicate options of: one or more A; one or more B; one or more C; one or more A and one or more B; one or more B and one or more C; one or more A and one or more C; and one or more of A, one or more of B, and one or more of C. Similarly, a list preceded by “a plurality of” (and variations thereon) and including “or” to separate listed elements indicates options of multiple instances of any or all of the listed elements. For example, the phrases “a plurality of A, B, or C” and “two or more of A, B, or C” indicate options of: A and B; B and C; A and C; and A, B, and C.

In some implementations, devices or systems disclosed herein can be utilized, manufactured, installed, etc. using methods embodying aspects of the disclosure. Correspondingly, any description herein of particular features, capabilities, or intended purposes of a device or system is generally intended to include disclosure of a method of using such devices for the intended purposes, of a method of otherwise implementing such capabilities, of a method of manufacturing relevant components of such a device or system (or the device or system as a whole), and of a method of installing disclosed (or otherwise known) components to support such purposes or capabilities. Similarly, unless otherwise indicated or limited, discussion herein of any method of manufacturing or using for a particular device or system, including installing the device or system, is intended to inherently include disclosure, as embodiments of the disclosure, of the utilized features and implemented capabilities of such device or system.

In some embodiments, aspects of the disclosure, including computerized implementations of methods according to the disclosure, can be implemented as a system, method, apparatus, or article of manufacture using standard programming or engineering techniques to produce software, firmware, hardware, or any combination thereof to control a processor device (e.g., a serial or parallel general purpose or specialized processor chip, a single- or multi-core chip, a microprocessor, a field programmable gate array, any variety of combinations of a control unit, arithmetic logic unit, and processor register, and so on), a computer (e.g., a processor device operatively coupled to a memory), or another electronically operated controller to implement aspects detailed herein. Accordingly, for example, embodiments of the disclosure can be implemented as a set of instructions, tangibly embodied on a non-transitory computer-readable media, such that a processor device can implement the instructions based upon reading the instructions from the computer-readable media. Some embodiments of the disclosure can include (or utilize) a control device such as an automation device, a special purpose or general-purpose computer including various computer hardware, software, firmware, and so on, consistent with the discussion below. As specific examples, a control device can include a processor, a microcontroller, a field-programmable gate array, a programmable logic controller, logic gates etc., and other typical components that are known in the art for implementation of appropriate functionality (e.g., memory, communication systems, power sources, user interfaces and other inputs, etc.). In some embodiments, a control device can include a centralized hub controller that receives, processes and (re) transmits control signals and other data to and from other distributed control devices (e.g., an engine controller, an implement controller, a drive controller, etc.), including as part of a hub-and-spoke architecture or otherwise.

The term “article of manufacture” as used herein is intended to encompass a computer program accessible from any computer-readable device, carrier (e.g., non-transitory signals), or media (e.g., non-transitory media). For example, computer-readable media can include but are not limited to magnetic storage devices (e.g., hard disk, floppy disk, magnetic strips, and so on), optical disks (e.g., compact disk (CD), digital versatile disk (DVD), and so on), smart cards, and flash memory devices (e.g., card, stick, and so on). Additionally, it should be appreciated that a carrier wave can be employed to carry computer-readable electronic data such as those used in transmitting and receiving electronic mail or in accessing a network such as the Internet or a local area network (LAN). Those skilled in the art will recognize that many modifications may be made to these configurations without departing from the scope or spirit of the claimed subject matter.

Certain operations of methods according to the disclosure, or of systems executing those methods, may be represented schematically in the FIGS., or otherwise discussed herein. Unless otherwise specified or limited, representation in the FIGS. of particular operations in particular spatial order may not necessarily require those operations to be executed in a particular sequence corresponding to the particular spatial order. Correspondingly, certain operations represented in the FIGS., or otherwise disclosed herein, can be executed in different orders than are expressly illustrated or described, as appropriate for particular embodiments of the disclosure. Further, in some embodiments, certain operations can be executed in parallel, including by dedicated parallel processing devices, or separate computing devices configured to interoperate as part of a large system.

As used herein in the context of computer implementation, unless otherwise specified or limited, the terms “component,” “system,” “module,” “block,” and the like are intended to encompass part or all of computer-related systems that include hardware, software, a combination of hardware and software, or software in execution. For example, a component may be, but is not limited to being, a processor device, a process being executed (or executable) by a processor device, an object, an executable, a thread of execution, a computer program, or a computer. By way of illustration, both an application running on a computer and the computer can be a component. One or more components (or system, module, and so on) may reside within a process or thread of execution, may be localized on one computer, may be distributed between two or more computers or other processor devices, or may be included within another component (or system, module, and so on).

Also as used herein, unless otherwise limited or defined, the terms “about,” “substantially,” and “approximately” refer to a range of values±5% of the numeric value that the term precedes. As a default the terms “about” and “approximately” are inclusive to the endpoints of the relevant range, but disclosure of ranges exclusive to the endpoints is also intended.

Also as used herein, unless otherwise limited or defined, “integral” and derivatives thereof (e.g., “integrally”) describe elements that are manufacture as a single piece without fasteners, adhesive, or the like to secure separate components together. For example, an element stamped as a single-piece component from a single piece of sheet metal, without rivets, screws, or adhesive to hold separately formed pieces together is an integral (and integrally formed) element. In contrast, an element formed from multiple pieces that are separately formed initially then later connected together, is not an integral (or integrally formed) element.

Also as used herein, unless otherwise defined or limited, the term “lateral” refers to a direction that does not extend in parallel with a reference direction. A feature that extends in a lateral direction relative to a reference direction thus extends in a direction, at least a component of which is not parallel to the reference direction. In some cases, a lateral direction can be a radial or other perpendicular direction relative to a reference direction.

The following discussion is presented to enable a person skilled in the art to make and use embodiments of the disclosure. Various modifications to the illustrated embodiments will be readily apparent to those skilled in the art, and the generic principles herein can be applied to other embodiments and applications without departing from embodiments of the disclosure. Thus, embodiments of the disclosure are not intended to be limited to embodiments shown but are to be accorded the widest scope consistent with the principles and features disclosed herein. The following detailed description is to be read with reference to the figures, in which like elements in different figures have like reference numerals. The figures, which are not necessarily to scale, depict selected embodiments and are not intended to limit the scope of embodiments of the disclosure. Skilled artisans will recognize the examples provided herein have many useful alternatives and fall within the scope of embodiments of the disclosure.

Liquid cooling systems can be provided in data centers to cool electrical equipment (e.g., computing nodes, storage nodes, networking devices, etc.) within a data center. Electrical equipment can be arranged within a rack of a data center, and racks of electrical equipment can be arranged in rows of racks of electrical equipment. Liquid coolant can be provided to the electrical equipment of the data center along one or more cooling circuits, and coolant distribution units can be provided to process the liquid coolant. A coolant distribution unit can include heat exchange elements to transfer a heat from the fluid to an air, for example, or from the fluid to a refrigerant or other liquid coolant. A coolant distribution unit can further include one or more pumps to induce a fluid flow through the liquid cooling circuit.

It can be advantageous to filter liquid coolant that flows to electrical equipment within a data center. For example, liquid cooling systems (e.g., the liquid cooling system described above) can include filtration assemblies to filter a liquid coolant before the liquid coolant is provided to racks of electrical equipment. In some cases, filtration assemblies can be positioned upstream of component that can be negatively affected by contaminates and particulate matter within a liquid coolant. For example, a liquid-to-liquid heat exchanger or a liquid-to-liquid heat exchanger can include a plurality of coils for effecting a heat transfer and build-up of particulate matter in the coils can reduce a cooling efficiency of the heat exchanger and increase a pressure drop across the heat exchanger. Filtration assemblies according to the present disclosure can remove impurities and particulate matter in a liquid cooling circuit (e.g., in liquid coolant of the coolant loop) that may otherwise damage downstream electrical equipment or degrade a cooling efficiency of the coolant loop.

In some cases, a filter of a filtration assembly can require maintenance or replacement. For example, in the course of operating a liquid cooling system, particulate matter can accumulate in a filter of a filtration assembly. This accumulated particulate matter can restrict a flow of fluid through the filter, decrease a performance of the filter, and increase a pressure required from pumping systems of a liquid cooling system to induce a flow of fluid through the filtration assembly. It can be advantageous to provide features for a filtration assembly that can facilitate a maintenance or replacement of a filter of the filtration assembly without requiring a stoppage of flow of fluid through the system (e.g., without causing a downtime to the liquid cooling system). Examples of the present disclosure can provide redundant filters for a filtration assembly that can allow fluid to flow through and be filtered by the filtration assembly, even in cases where a filter is removed for servicing.

Filtration assemblies according to the present disclosure can include one or more parallel filters (e.g., canister strainers) along respective flow paths. Electromechanical valves can be provided along the parallel flow paths (e.g., upstream and downstream of a corresponding filter), and can automatically start or stop flow to either of the parallel filters independently for operation or service. In other embodiments, manual valves may be used to start or stop flow to a filter of a filtration assembly. In some cases, control systems can be provided for filtration systems and can operate valves of a filtration assembly to implement different operational modes for flow through the filtration assembly (e.g., parallel flow, failover, active-passive, flow balancing, etc.). Control systems of a liquid cooling system can operate valves of a filtration assembly to achieve desired flow, desired pressure characteristics, or otherwise operate the valves in response to sensed values of the filtration assembly.

It can be advantageous to electronically monitor filters and filtration assemblies and automatically perform remedial measures (e.g., bypassing a filter requiring maintenance, balancing a load between parallel filters, generating an alert, etc.). In some cases, valves can be provided along a filtration assembly to selectively allow or deny flow through a filter or through one or more parallel flow paths of a filtration assembly. In some cases, valves of a filtration assembly can be manually operated. In other embodiments, electromechanical valves (e.g., including servo motors, linear actuators, etc.) can be operated electronically either in response to an electronic signal (e.g., a signal provided by a control system, a signal manually generated by a user at an input, etc.).

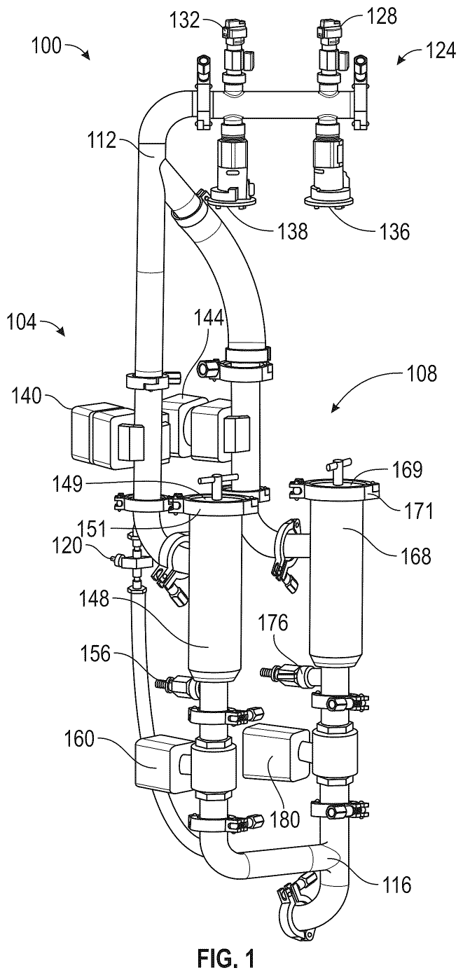

In this regard, FIG. 1 illustrates an example of a filtration assembly 100 including redundant flow lines 104, 108, according to some aspects of the present disclosure. The filtration assembly 100 can be provided along a liquid cooling circuit, and can include piping or hosing to integrate with the liquid cooling circuit. As shown, the filtration assembly 100 defines a unified inlet 116, and a unified outlet 112. The unified inlet 116 can provide a single point of entry of fluid into the filtration assembly 100, and the unified outlet 112 can define a single point of egress of fluid from the filtration assembly 100. In the illustrated embodiment, the unified inlet 116 is below the unified outlet 112 (e.g., in the direction of gravity) and flow of fluid opposes the direction of gravity. In other examples, a fluid can flow through a filtration assembly in the direction of gravity. As shown in FIG. 1, the filtration assembly 100 comprises a first flow line 104, a second flow line 108, a unified inlet 112, a unified outlet 116, and a differential sensor 120. In the illustrated example, the unified inlet 116 is upstream of both of the first and second flow lines 104, 108, and the unified outlet 112 is downstream of both of the first and second flow lines 104, 108. While the illustrated example shows two flow lines, in some examples, filtration assemblies can include more than two flow lines, each flow line including a corresponding filter and filter housing.

In some conventional filtration assemblies, servicing or replacing a filter can require stopping a flow of fluid through a filtration assembly while the filter is being serviced. This can cause an undesirable downtime in a cooling system, which, in turn can produce a negative effect on a performance of downstream electrical equipment (e.g., by causing a downtime in the downstream electrical equipment or by an increased heat of the electrical equipment when liquid cooling is paused). According to some aspects of the present disclosure, filtration assemblies can include parallel flow paths (e.g., two parallel flow paths, three parallel flow paths, etc.), each parallel flow path being in fluid communication with an inlet and an outlet of the filtration assembly. One of more parallel flow paths of a filtration can include a filter. When a filter along a parallel flow path of a filtration assembly is being serviced or replaced, flow can be diverted to the other parallel flow path, which can allow an operation of a liquid cooling system to continue during servicing of a filter along a liquid flow path.

According to some examples, flow lines of a filtration system can include similar (e.g., identical) components, and can provide redundancy for the system, as can advantageously allow the filtration system to continue operation when one or more components of a flow line fails or undergoes maintenance. Still referring to FIG. 1, the first flow line 104 a first entry valve 160, a first filter housing 148 housing a cannister filter 149, a first drain port 156, and a first exit valve 140. The cannister filter 149 can be secured to the filter housing 148 with a clamp 151. The clamp 151 can be a clamp of a tri-clamp fitting that engages a flange of the filter 149 and a flange of the filter housing 148 to secure the filter 149 to the filter housing 148, and provide a seal between the filter 149 and the filter housing 148. In other examples, a filter can be secured within a filter housing via other arrangements, including, for example, through a threaded engagement between the filter and the filter housing. As shown, the first entry valve 160 is provided upstream of both of the filter housing 148 and the drain port 156, and the first exit valve 140 is provided downstream of both of the filter housing 148 and the drain port. Both of the valves 140, 160 can be controlled to be movable between an open configuration (e.g., an open position) in which fluid flow is allowed through the valve 140, 160 and a closed configuration (e.g., a closed position) in which fluid is not allowed to flow through the respective valve 140, 160. When both of the valves 140, 160 are in the open configuration, a fluid can flow through the filter housing 148 and the filter 149 (e.g., from the unified inlet 116 to the unified outlet 112). When one or both of the valves 140, 160 is in the closed configuration, a flow of fluid is blocked through the first flow line 104. In an example, filters of a filtration assembly (e.g., the cannister filter 149) can be strainer filters comprising a 50 micron washable wedge wire screen.

In the illustrated example, both of the valves 140, 160 are electronically-actuated two-way ball valves. The valves 140, 160 can be moved between an open configuration and a closed configuration in response to a signal from a controller (e.g., in response to a user input, a sensed parameter, etc.). In some cases, entry and exit valves (e.g., isolation valves) can be manual valves, and a handle can be provided for the valves to allow a user to rotate the valve between an open and a closed configuration. In some cases, valves along a first flow line can be positioned in an intermediate configuration, as can restrict a flow of fluid through the filter and filter housing of the flow line without completely stopping a flow of fluid through the flow line. In some cases, valves of a flow line of a filter assembly can comprise other valve types, including, for example, three-way ball valves, needle valves, globe valves, gate valves, solenoid-actuated valves etc. In some embodiments, the first entry valve 160 and first exit valve 140 may be substantially identical valves. For example, the first entry valve and first exit valve may be manual two-way ball valves. In FIG. 1, the first entry valve 140 and first exit valve 160 are depicted as actuated two-way ball valves. In other embodiments, the first entry valve and the first exit valve may be substantially different valves. For example, the first entry valve may be a manual two-way valve while the first exit valve may be a solenoid valve. In some embodiments, the first entry valve and first exit valve may be a combination of manual two-way ball valves, manual two-way ball valves, solenoid valves, or actuated two-way valves.

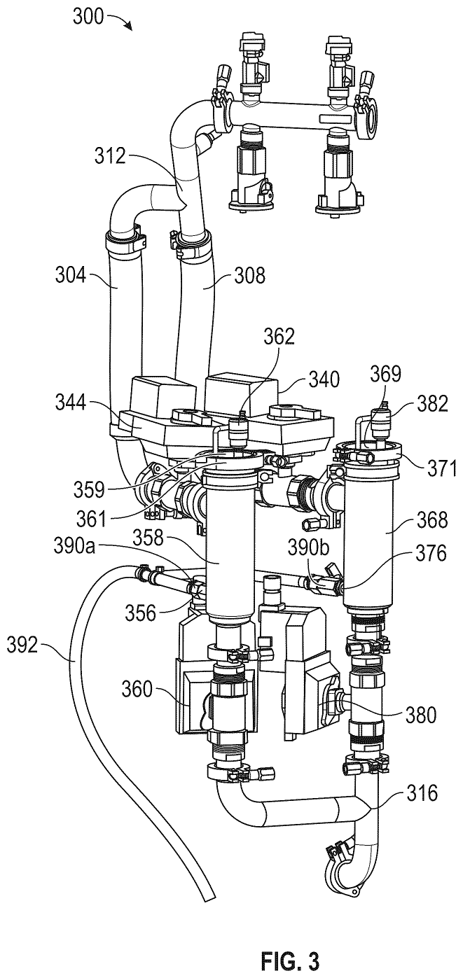

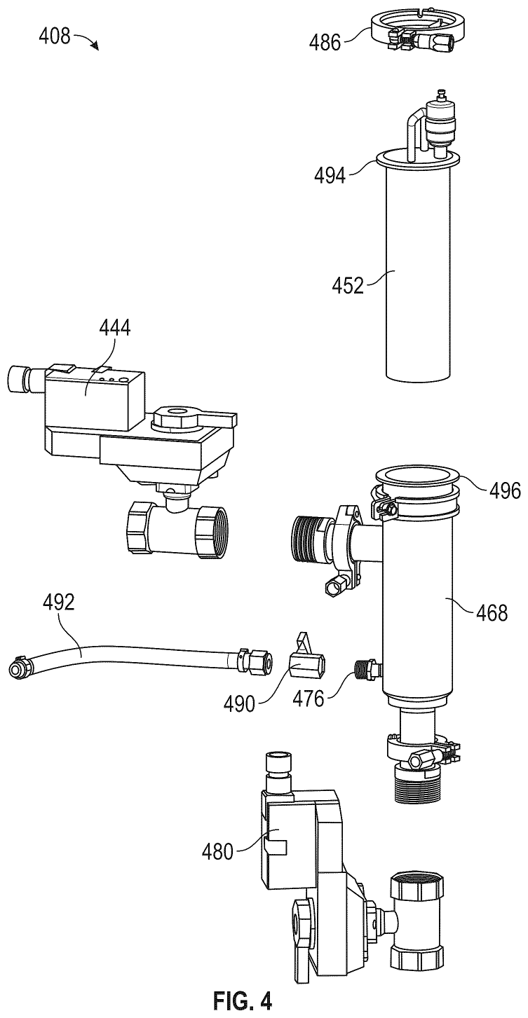

In operation, a fluid flowing through a flow line of a filtration assembly can be pressurized, and it can be advantageous to reduce a pressure of the fluid before removing a filter for servicing, as can prevent a spray of fluid from the flow line when it is opened for servicing. It can be advantageous to provide features and components to fluidly isolate a filter housing and filter from a liquid cooling circuit (e.g., to stop a flow of fluid through the filter housing) and further provide systems for relieving a fluid pressure within the housing before removing the filter for servicing. In this regard, referring to the first flow line 104, the valves 140, 160 can be moved to a closed configuration before a servicing of the filter 149. When the valves 140, 160 are in the closed position, the filter housing 148 is fluidly isolated from the unified inlet 116 and the unified outlet 112. As noted above, the drain valve 156 can be provided fluidly between the entry valve 160 and the exit valve 140. In advance of a servicing of the filter 149, a fluid can be drained from the filter housing 148 through the drain port 156, as can reduce a fluid pressure within the filter housing 148 and prevent a spray of fluid when the clamp 151 is disengaged. In the illustrated example, the drain port 156 is provided below the filter housing 148 (e.g., in the direction of gravity), as can advantageously promote a drainage of fluid through the drain port (e.g., due to a pressure generated by gravity). In some cases, the drain port 156 can comprise a quick disconnect port that can allow a fluid flow through the port when a hose with a corresponding quick-disconnect fitting is attached. In some cases, (as shown, e.g., in FIGS. 3 and 4), a drain port of a flow line can include a manually engageable drain valve, and an operator can move the drain valve between an open and a closed position to allow or deny a flow of fluid through the drain port.

In some examples, a first and second flow line can be substantially identical (e.g., can include the same components arranged in the same order). As illustrated, the second flow line 108 is substantially similar to the first flow line, and the description of the elements of the first flow line 104 is applicable to the corresponding components of the second flow line 108. For example, the second flow line includes an entry valve 180, a drain port 176, a filter housing 168, a filter 169 secured within the filter housing 168 with a clamp 171, and an exit valve 144. In some cases, providing redundant flow lines with similar components can allow an operator to operator a filter assembly in various different modes. For example, in some cases, the first flow line 104 can be a primary flow line, and the second flow line 108 can be a secondary flow line, and the valves 140, 160, 144, 180 can operate to allow flow through the first flow line 104 by default and deny flow through the second flow line 108 by default. In some cases, the valves 140, 160, 180, 144 can be in an open configuration by default (e.g., in an active-active mode) to allow flow through both of the flow lines simultaneously. In some cases, the valves 140, 160, 180, 144 can operate to balance a flow through the flow lines 104, 108 to facilitate an equal wear of components along both flow lines. Other configurations are possible, however, an valves of a filter assembly can be operated according to manual instructions or automated control algorithms to implement custom operating modes for a filtration assembly.

A restriction in flow through one or more filters of a filtration assembly (e.g., due to an accumulation of particulate matter within a filter) can increase a pressure difference between a filter inlet and outlet. According to some aspects of the present disclosure, filtration assemblies can include sensors for detecting a pressure difference across one or more filters, and control systems of a liquid cooling system can perform operations in response to a sensed pressure difference across a filter (e.g., generate an alert, alter a flow path through operation of one or more valves, isolate the filter experiencing the pressure difference, etc.). As further shown in FIG. 1, the differential sensor 120 is provided along the filtration assembly 100, and can sense a pressure differential across one or both of the flow lines 104, 108. In some cases, for example, the differential pressure sensor can sense a difference between a pressure at the unified inlet 116 and the unified outlet 112. In some cases, the differential pressure sensor 120 can sense a pressure difference immediately upstream and downstream of the first filter housing 148 or the second filter housing 168. In some examples, a filter assembly can include multiple differential pressure sensors (e.g., a differential pressure sensor for each flow line). In some cases, a filter assembly does not include a differential pressure sensor. For example, individual pressure sensors can be provided along the a filter assembly, and a pressure drop across the filter assembly, or across individual flow lines of the assembly can be determined from readings of the individual pressure sensors. In some examples, the differential pressure sensor 120 can be integrated with a control system for the filtration assembly 100, and is a differential pressure measured by the differential pressure sensor meets or exceeds a pressure threshold, an automated action can be triggered. For example, an alert can be generated at a user interface, a LED of a control panel can indicate a need for servicing, valves of a filter assembly can be operated to fluidly isolate a filter and filter housing from a flow of fluid through the filtration assembly, etc. In some cases, a pressure difference of greater than or equal to 1.5 pounds per square inch (psi) can indicate a need for servicing of a filter, and when the differential pressure sensor measures a pressure difference of greater than or equal to 1.5 psi, an action can be initiated (e.g., an alert can be generated, a LED can be activated, valve positions can be changed, etc.). In some cases, a pressure threshold can be between about 1.5 psi and about 3 psi.

In some examples, the filtration assembly 100 can be a filtration assembly for a liquid cooling system in a data center (e.g., a liquid-to-air coolant distribution unit). In other cases, the disclosed filtration assemblies can be usable in other fluid flow applications (e.g., in domestic or industrial water filtration systems). As depicted in FIG. 1, the filtration assembly includes a manifold 124. In some embodiments, the filtration assembly does not comprise a manifold. In the depicted embodiment in FIG. 1, the manifold 124 comprises a first sensor 128, a second sensor 132 that is downstream of the first sensor 128, a first fluid port 136 proximate the first sensor 128, and a second fluid port 138 proximate the second sensor 132. The first and second sensors can provide metrics that may be used to assess the obstruction of flow through the selected flow line. For example, if fluid is flowing through the first and second flow lines, the metrics measured in the first and second sensors may be compared to those of the sensor that is within the flow line and determine if the flow line is impeded.

In some cases, air can be introduced into filtration assemblies for liquid cooling systems when filters are installed and removed. Air bubbles within a fluid flow line for cooling systems can degrade system performance and damage components. According to some embodiments, elements can be provided to mitigate the effect of air bubbles. For example, the first filter housing may contain an air vent (not shown). The air vent may operate automatically and be integrated into the first filter housing. Further, the air vent is located at the highest point of the flow line before the first filter housing, or at the highest point of the first filter housing.

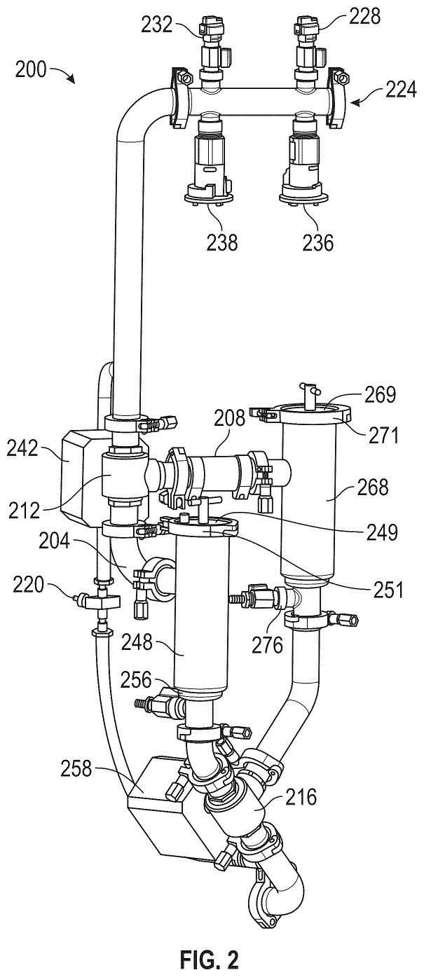

Filtration assemblies can be configured to optimize a flow of fluid by equally distributing fluid to redundant flow lines and corresponding filters of the filtration assemblies. Further, in some cases, filtration assemblies can be provided to reduce a number of valves required to operate redundant flow lines, as can advantageously reduce a total cost of the system. Another example of a filtration assembly 200 is depicted in FIG. 2, according to some aspects of the present disclosure. In FIG. 2, the filtration assembly 200 may be similar to the filtration assembly depicted in FIG. 1, and includes similar numbering for similar components. In some cases, the filtration assembly 200 of FIG. 2, with the exception of a main entry valve and main exit valve, can be identical to the filtration assembly of FIG. 1. For example, as shown, the filtration assembly 200 includes a unified inlet 216, a first flow line 204, a second flow line 208, and a unified outlet 121. The first flow line includes a drain port 256, a filter housing 248, a filter 249, and a clamp 251 securing the filter 249 to the filter housing. Similarly, the second flow line includes a drain port 276, a filter housing 268, a filter 269, and a claim 271 securing the filter 269 to the filter housing 268.

As shown in FIG. 2, an entry valve 258 can be provided at the unified inlet 216, and an exit valve 242 at the unified outlet 212. Both of the entry valve 258 and the exit valve 242 can be actuated three-way ball valves (e.g., three-way ball valves actuated by solenoids, servo motors, etc.). Each of the valves 258, 242 can define a first position (e.g., a closed position), in which flow is denied through the valve, a second position in which flow is allowed through the first flow line 204, and a third position in which flow is allowed through the second flow line 208. In some cases, the valves 258, 242 can further include a position allowing a flow of fluid through both the first and second flow lines 204, 208. The filter assembly of FIG. 2 can thus reduce a system complexity by reducing a number of electromechanical components usable in the assembly 200. In the illustrated example, the entry valve 258 and exit valve 242 may be substantially identical valves. In other embodiments, the main entry valve and the main entry valve may be substantially different valves. For example, the main entry valve may be a manual three-way valve while the main exit valve may be an actuated three-way valve. In some examples, an entry valve and an exit valve may be manual three-way valves. The configuration of dual manual three-way valves can reduce a cost and complexity of a system.

In some cases, a physical arrangement of flow lines and components thereof can advantageously equalize a pressure drop across redundant filter assemblies, and optimize a usage of space within a cooling system (e.g., a coolant distribution unit). In some examples, it may be advantageous to include a “y” piping arrangement at an inlet into the first and second flow lines. A “y” piping arrangement may allow for the respective flow lines to have a substantially similar, and in some cases, substantially identical, pressure profile, e.g., the flow lines have the substantially similar pressure distribution along the fluid flow paths. As shown, the entries into the first flow line 204 and the second flow line 208 can be angled outwardly from each other relative to the unified inlet 216 (e.g., can be arranged as a “y”). An angle between the flow lines 204, 208 can be selected to equalize a pressure profile along the first and second flow lines 204, 208 in light of the physical parameters of the flow lines 204, 208. In some cases, a filter housing and filter of one flow line can be positioned at a different height (e.g., relative to the direction of gravity), as can further allow a control of a pressure difference between flow lines. For example, as shown, the filter housing 268 is offset in a height direction from the filter housing 248. In some cases, filter housings can be positioned at substantially the same (e.g., the same) height, as shown, for example, in FIGS. 1 and 3.

In FIG. 2, upstream of the differential sensor 220 is a manifold 224, similar to that of FIG. 1. In some embodiments, the filtration assembly does not comprise a manifold. In the depicted embodiment of FIG. 2, the manifold 224 comprises a first sensor 228, a second sensor 232 that is downstream of the first sensor 228, a first fluid port 236 proximate the first sensor 228, and a second fluid port 238 proximate the second sensor 232. The first flow line 204 of FIG. 2 comprises a first filter housing 248 containing a first filter (not shown) and a first drain port 256.

Another embodiment of a filtration assembly 300 is depicted in FIG. 3. In the embodiment depicted in FIG. 3, the filtration assembly 300 may include substantially similar components to that of the filtration assembly 100 of FIG. 1. For example, the filtration assembly 300 includes a unified inlet 316, a unified outlet 312, with a first flow line 304 and a second flow line 308 positioned fluidly between the unified inlet 316 and the unified outlet 312. The first flow line 304 includes a first entry valve 360, a first filter housing 358 containing a first filter 359 secured to the first housing 358 with a clamp 361, a first drain port 356, and a first exit valve 344. The filtration assembly 300 also includes a second flow line 308. The second flow line 308 in FIG. 3 is substantially identical to the first flow line 304, although variations for the filtration assembly 300 are possible. In the embodiment of FIG. 3, the second flow line 308 includes a second entry valve 380, a second filter housing 368 containing a second filter 369 secured to the second filter housing 368 with a second clamp 371, a second drain port 376, and a second exit valve 340.

In the illustrated example, the drain ports 356, 376 each comprise a drain valve 390a, 390b respectively. The drain valves 390a, 390b comprise handles that can be engaged by an operator to drain fluid from the respective housings 358, 368 when the valves 390a, 390b are open. Hosing 392 can be connected to the drain ports 390a, 390b to allow an operator to drain the fluid to a selected location. For example, in some cases, a reservoir can be provided in a bottom portion of a CDU, or in some instances an operator can drain the fluid into a tank, a bucket, to a drain in a floor, etc.

In some instances, particularly after maintenance of a filtration assembly, air must be removed, or purged, from flow lines. In the filtration assembly 300 of FIG. 3, the first flow line 304 includes a first air bleed valve 362 and the second flow line 308 includes a second air bleed valve 382. In the embodiments filtration assembly depicted in FIG. 3, the first and second air bleed valves 362, 382 are located on the highest point of the filtration housings 358, 368 of each respective flow line 304, 308. In the illustrated example, the air bleed valves 362, 382 are installed on a top of the respective filters 359, 369. In some embodiments, the air vents automatically purge the air from the flow lines. For example, an air within filter housing 358 can rise to a top of the housing, and a fluid pressure within the housing 358 can push the air out through the air bleed valve 362 . . . . In other embodiments, air bleed valves can be manually activated (e.g., opened, loosened, etc.) to purge air from the flow lines.

During operation of a filtration assembly, a filter may need to be replaced. As such, the filter must be removed from a filter housing. As described above, in some examples, the filter is secured within the filtration housing via a clamp. In some examples, the clamp is a clamp that is compatible with tri-clamp fittings. In other embodiments, the clamp is a split band clamp, a saddle clamp, or other clamps know to those skilled in the art. FIG. 4 illustrates an exploded view of a portion of a flow line 408, according to some examples. The flow line 408 can be substantially similarly to any of the flow lines 104, 108, 204, 208, 304, 308 described above in FIGS. 1-3. For example, as shown in the exploded partial view of FIG. 4 the flow line 408 includes a filter housing 468, a filter 452, an entry valve 480, an exit valve 444, a drain port 476, a drain valve 490, and a drainage hosing 492, and a clamp 486. As shown the filter 452 includes a radial flange 494, and the filter housing includes a radial flange 496. The flanges 494, 496 of the filter 452 and the filter housing 468 can be of a similar or identical diameter. The filter 452 is secured to the filtration housing 468 via a clamp 486, with both of the radial flanges 494, 496 being received by and enveloped by the clamp 486.

In some aspects of the disclosure, a panel is provided to indicate a current operation of a flow line. In some embodiments, the panel indicates a current state of operation of a filter housing. In some aspects, the panel may include one or more visual indicators that may indicate the current state of operation. For example, the panel may include one visual indicator that indicates if the filter housing, and therefore flow line, is active (e.g., in use, fluid is flowing through the flow line). The one or more visual indicators may flash, pulse, turn on/off, etc. to depict various states of operation. For example, one of the one or more visual indicators may flash or pulse when a flow line is undergoing a process. In other examples, the one or more visual indicators may turn off, or change colors, to depict a change in the state of operation. In some cases, an indicator can be activated to communicate that a pressure difference across one or more filters or filter housings meets or exceeds a pressure threshold.

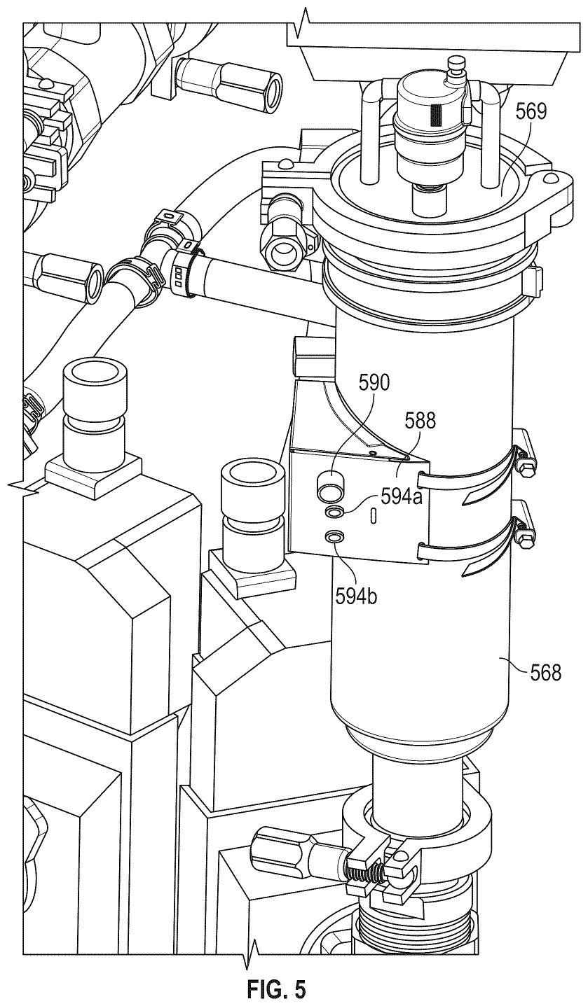

In some examples, a panel may also include a button, wherein the button may be used to begin a process or task. In other examples, the panel may include a switch, a knob, turn dial, or something of the like that may be switched, turned, twisted, etc. to begin a process. In some cases, a panel can be software defined, and can be accessed via a user interface (e.g., a touch screen panel of a CDU, or a user interface accessible via a network, etc.). FIG. 5 illustrates a panel 588 including control inputs and indicators. As shown, the panel 588 is secured to a filter housing 568, and can provide controls and indicators for controlling the particular flow line corresponding to the filter housing 568. In other examples, a panel for a flow line can be mounted elsewhere along a filtration assembly, within a housing housing the filtration assembly, or can be software-defined. In the illustrated example, as shown, the panel 588 include a first visual indicators 594a (e.g., a LED) and a second visual indicator 594b. The illustrated panel 588 further includes a button 590. The button may be used to initiate a process, e.g., a process for servicing a flow line, a process for starting up a flow line after service, a switchover between flow lines, or any other process discuss below. For example, an operator can press the button 590 to initiate a servicing of the filter 569, and in response, valves upstream and downstream of the filter housing 568 can be closed to fluidly isolate the filter housing 568. In an example, the indicator 594a can be illuminated to indicate that the filter 569 is active (e.g., fluid is flowing through the housing 568). The indicator 594b can be illuminated to indicate that the filter 569 is inactive (e.g., the filter housing 568 is fluidly isolated). In some cases, one or both of the indicators 594a, 594b can blink or flash to indicate that a filling or draining is in process. In some examples, a panel includes one visual indicator (e.g., a visual indicator capable of being illuminated with different colors and blinking frequencies). In other examples, a panel does not include a visual indicator, or includes more than three visual indicators. In other examples, the panel 588 includes more than two visual indicators. Panels (e.g., similar or identical to panel 588) can be provided for each flow line of a filtration assembly. For example, panels can be installed on both of filter housing 368 and filter housing 358 shown in FIG. 3. In some cases, a single panel can be provided for a filtration assembly and can include controls and visual indicators for each flow line of the filtration assembly.

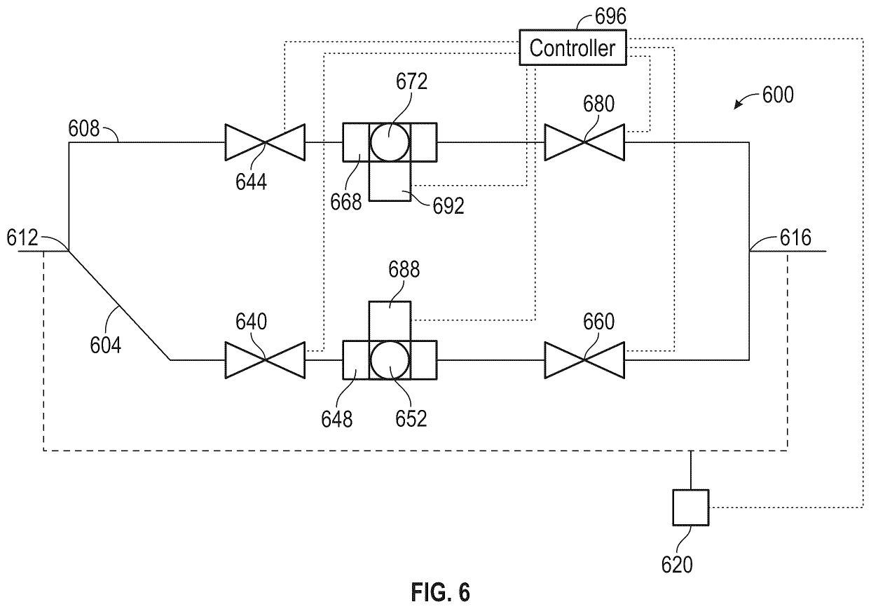

FIG. 6 illustrates an example schematic plumbing and control diagram of a filtration assembly 600, and redundant first and second flow lines 604, 608 (e.g., similar or identical to flow lines 104, 108, 204, 208, 304, 308, 408 described above with respect to FIGS. 1-4) positioned fluidly between a unified inlet 612 and a unified outlet 616. FIG. 6 includes substantially similar numbering for similar components depicted in FIG. 3 in the 600 series. In some cases, the filtration assembly 600 of FIG. 6 can be substantially identical to the filtration assembly 300 of FIG. 3. The filtration assembly 600 of FIG. 6 can also have more or fewer valves, sensors, and the like than that of FIG. 3.

As shown in FIG. 6, the first flow line 604 of FIG. 6 includes a first entry valve 640, a first filter housing 648 with a first filter 652, a first panel 688, and a first exit valve 660. The second flow line 608 of FIG. 6 is identical to the first flow line 604 of FIG. 6, comprising a second entry valve 644, a second filter housing 668 with a second filter 672, a second panel 692, and a second exit valve 680. The unified outlet 616 is downstream of the first and second flow lines 604, 608, and the unified inlet 612 is upstream of the first and second flow lines 604, 608. As shown, the filtration assembly 600 includes a differential pressure sensor 620 (e.g., similar or identical to differential pressure sensor 120 shown in FIG. 1).

Electrical and electro mechanical elements of a filtration assembly (e.g., valves, panels, indicators, controls, sensors, etc.) can be in communication with a controller, which can collect telemetry from sensors and states of the elements, and can further receive control signals and control elements of the filtration assembly. In the example plumbing schematic of FIG. 6, the filtration assembly 600 may include a controller 696. The controller 696 may be in electrical communication with various components of the filtration assembly 600. In the example plumbing schematic of FIG. 6, the dot-dot-dot lines depict electrical communication. For example, the controller 696 may be in electrical communication with the first entry valve 640, the second entry valve 664, the first exit valve 660, the second exit valve 680, the first panel 688, the second panel 692, and the differential sensor 620.

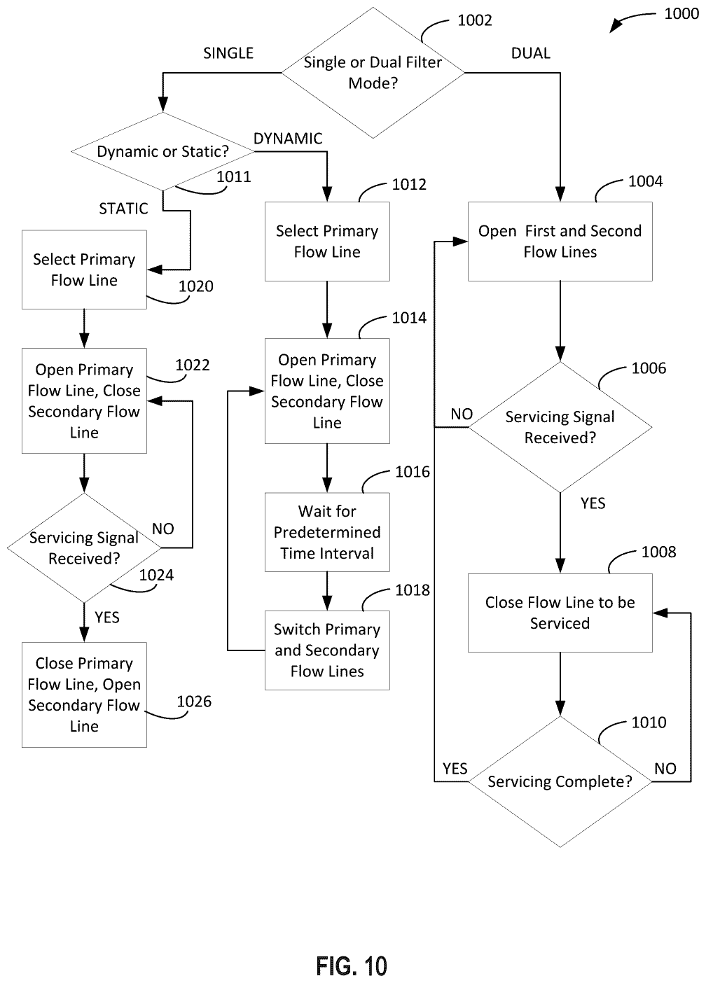

A controller of a filter assembly (e.g., the controller 696 of filter assembly 600 shown in FIG. 6) can implement various operating modes of operation for the filter assembly. In one example, operating modes for a filter assembly can include a dual filter mode, a static single filter mode, and a dynamic single filter mode (e.g., as shown and described with respect to FIG. 10). In some cases, an operating mode can be selected according to an algorithm or default accessible to the controller (e.g., stored in a memory of the controller, or as a parameter available to the controller through a remote connection, etc.). In some cases, an operating mode can be selected by an operator (e.g., via a control or an interface of the controller).

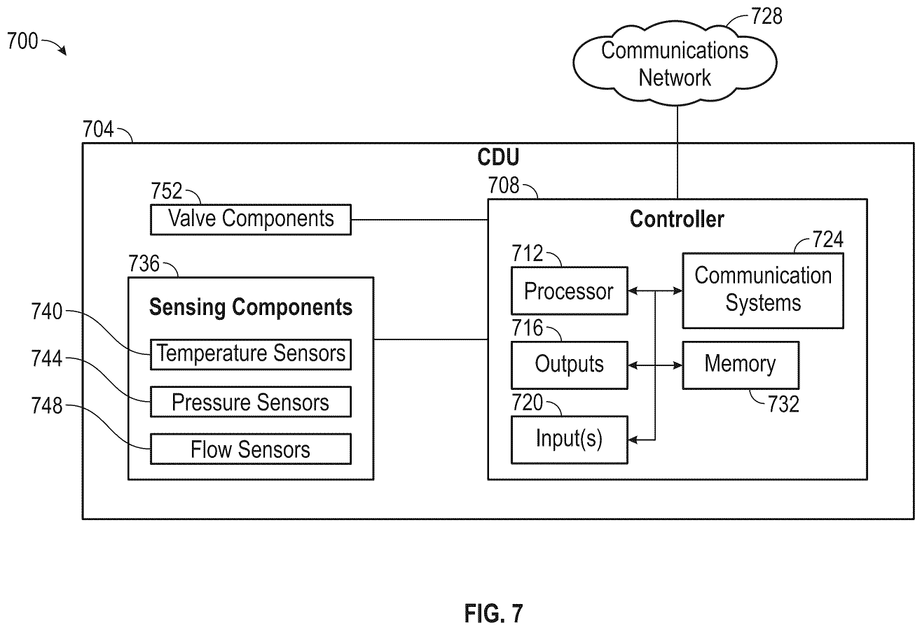

FIG. 7 illustrates a control schematic for a filtration assembly 700, which can include a controller 708, valve components 752, and sensing components 736. The controller 708 can be similar or identical to the controller 696 shown in FIG. 6, and the description of controller 708 can be applicable for the controller 696. In some examples, the controls systems of the filtration assembly 700 may be a control system of a CDU 704 (e.g., a unit housing pumps and heat exchangers for an air-to-liquid, liquid-to-liquid, liquid-to-air, or refrigerant based cooling). The controller 708 may include a processor 712, an output 716, one or more inputs 720 (e.g., one input, two inputs, three inputs, etc.), one or more communication systems 724 (e.g., one communication system, two communication systems, three communication systems, etc.), and/or a memory 732. In some embodiments, the processor 712 is a programmable logical controller (PLC). In other embodiments, the processor 712 can be a combination of hardware processors, such as a central processing unit (CPU) and/or a graphics processing unit (GPU) or the like. In some embodiments, the output 716 may include any display device, such as, a television, a computer monitor, a touch screen, or the like. The output can include visual indicators (e.g., the visual indicators 594a, 594b shown in FIG. 5). The one or more inputs 720 may be received in a variety of methods, such as a mouse, a touch screen, a keyboard, a microphone, a camera, a keypad, or the like. For example, the inputs can include a button of a panel (e.g., button 590 of panel 588 shown in FIG. 5) that can be configured to initiate a servicing (e.g., a removal or insertion) of a filter. The various user interfaces may allow the operator to set control parameters or view the system parameters, such as define and/or view set points for sensors, select and/or view which sensors to display, select and/or view the mode of operation, or the like.

In some embodiments, the one or more communication systems 724 may include any method for receiving and transmitting information over a communication network 728. For example, the one or more communication systems 724 may include one or more chip sets, one or more transceivers, one or more communication chips, and/or the like.

Still referring to FIG. 7, in some embodiments, the memory 732 may include any method or device suitable for storing instructions, values (i.e., values from sensors, inputs from operators, etc.), and/or the like. The values and/or instructions stored in the memory 732 can be used by the processor 712 to control the filtration assembly through implementing commands the CDU 704, store values of the controller 708, or the like. The memory 732 can consist of any volatile memory, non-volatile memory, storage, or any combination of such. In some embodiments, the memory 732 may include one or more flash, one or more hard disks, random access memory (RAM), read-only memory (ROM), or the like.

The filtration assembly 700, in some embodiments, may include sensing components 736. The sensing components can include sensors and/or mechanical components, such as valves, of the CDU. For example, the sensing components 736 of FIG. 7 can comprise temperature sensors 740, pressure sensors 744 (e.g., similar to differential pressure sensor 120, 620 shown in FIGS. 1 and 6), and flow sensors 748. In some cases, sensing components can include position sensors for valves of the filtration assembly 700, as can allow the controller 708 to implement a valve control (e.g., a PID control) to adjust a position of the valve components 752. The sensing components can be in communication with the controller 708.

Still referring to FIG. 7, valve components 752 may be in communication with the CDU 704. The valve components can include any or all the two-way valves or three-way valves. For example, the valve components may include the first entry valve, the first exit valve, the second entry valve, the second exit valve and any other valve components of the filtration assembly 700. In some embodiments, the controller can send a signal that commands the valve components to actuate, e.g., open, or close. In some embodiments, the controller can send a signal that partially opens or partially closed the valve components. In some embodiments, the controller can issue a signal that routes the fluid through the first flow line, or the second flow line, or a combination of both flow lines.

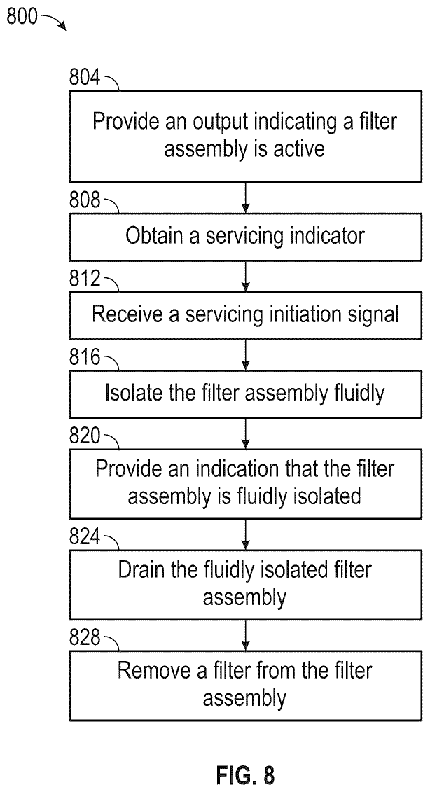

In some methods of operation, a filtration assembly may component that require maintenance, inspection, or any other instance that requires a flow line to temporarily cease in operation. Therefore, the filtration assembly required a method for isolating (e.g., shutting down flow) a flow line. FIG. 8 illustrates an example process 800 for removing a filter for servicing. In some cases, all or a portion of the process can be automated (e.g., steps of the process 800 can be implemented by a control system) and can be operated using a controller (e.g., one or both of controllers 708, 696, shown in FIGS. 7 and 6). In some cases, a portion of the process 800 can be performed manually by an operator of the filter assembly.

At block 804, the method can include outputting an indication that a filter is active (e.g., a fluid is flowing through the filter). In some examples, an output may be a visual indicator (e.g., the visual indicators 594a), a display, a user interface, or an output similar to the output 716 of FIG. 7. Additionally, the filter assembly may be substantially similar to any of the example filter assemblies shown FIGS. 1-5. The output can be a continuous output that is provided when the filtration assembly is active. In some cases, the output indicates that a portion of the filter assembly is active (e.g., the output corresponds to a give flow line of the filter assembly).

At block 808, the process can include obtaining a servicing indicator. A servicing indicator can include a signal indicating a condition of one or more filters of a filtration assembly. For example, the servicing indicator can comprise a measurement of a differential pressure sensor (e.g., differential pressure sensor 120 shown in FIG. 1) that is greater than or equal to a pressure threshold. In other examples, a servicing indicator can include any measurement or combination of measurements that can indicate a need for servicing one or more filters of a filter assembly. In some cases, in response to obtaining a servicing indicator at block 808, the control system can provide an alert or an indication to a user to communicate a needs for servicing the filter. An alert can be provided at a user interface, through a notification, at LEDS of a control panel (e.g., through activation, a change of color, a flashing, etc.) etc.

At block 812, the process 800 can include receiving a service initiation signal. In some cases, a service initiation signal can be provided by a user at an interface or control of a filter assembly. For example, a service initiation signal can be obtained via the button 590 shown in FIG. 5. The button can correspond to a particular flow line and filter of the filtration assembly. In some cases, a service initiation signal can be generated by a control system of a filtration assembly based on a servicing indicator (e.g., when a pressure drop across a filter exceeds a threshold pressure difference).

At block 816, all or a portion of a filter assembly can be fluidly isolated. In some cases, fluidly isolating all or a portion of a filter assembly can include providing a signal to valves of the filter assembly to close the valves to prevent a flow of fluid through the valves. For example, if the service initiation signal is received for the first flow line 304 shown in FIG. 3, a controller of the filter assembly can provide a signal to entry valve 360 and exit valve 344 to stop a fluid flow through the first flow line 304, and to fluidly isolate the filter housing 358 and the filter 359 from the filter assembly 300 (e.g., from the unified inlet 316 and the unified outlet 312).

At block 820, the process 800 can provide an indication that all or a portion of the filter assembly is fluidly isolated. For example, a controller (e.g., controller 696 shown in FIG. 6) can receive an indication that valves of the filter assembly are fully closed, and once the valves are fully closed, an indication can be provided to an operator (e.g., a visual indicator, an alert, a notification, an element on a user interface, etc.). For example, with reference to FIG. 5, when the filter housing 568 is fluidly isolated from the filter assembly, the visual indicator 594b can be activated (e.g., and the visual indicator 594a can be deactivated).

At block 824, the process 800 can include draining all or a portion of the filter assembly. As described above, it can be necessary to relieve a pressure within a portion of a filter assembly before removing a filter (e.g., to avoid a spray of fluid from the filter assembly). Draining a fluid can include connecting a hosing to a drain port of a flow line of a filter assembly. For example, with reference to FIG. 3, the filter housing 358 can be fluidly isolated from the unified inlet 316 and the unified outlet 312 through closure of the valves 344, 360. An operator can implement block 824 by opening the drain valve 390a to allow fluid to drain from the filter housing 358 through the hosing 392 (e.g., into a bucket or other reservoir).

At block 828, a filter can be removed from the filter assembly for servicing. With continued reference to the example of isolating the filter housing 358 described above, removing the filter 359 can include removing the clamp 361 securing the filter 359 to the filter housing 358. In some cases, the clamp 361 can be removes in a tool-less process, while in others, a torque wrench (e.g., an 11/16″ wrench) can be used to loosen a bolt and allow removal of the clamp. Once the clamp 361 is removed, an operator can grasp the filter 369 (e.g., at a handle of the filter 369) and lift the filter 369 from the filter housing 368).

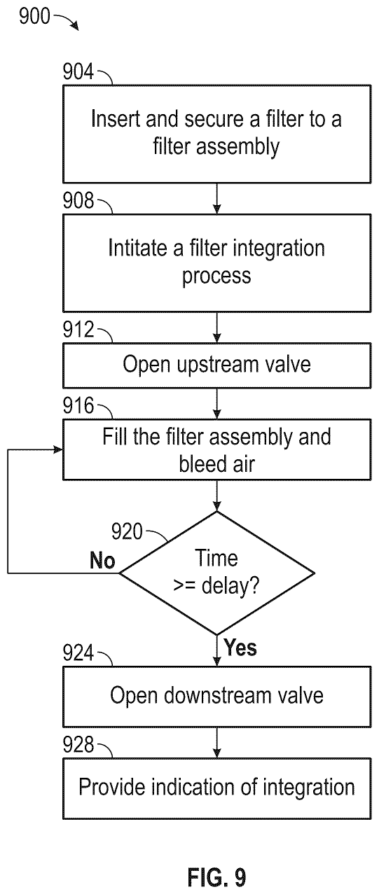

FIG. 9 illustrates an example process 900 for inserting a filter into a filter assembly. In some cases, all or a portion of the process can be automated (e.g., steps of the process 900 can be implemented by a control system) and can be operated using a controller (e.g., one or both of controllers 708, 696, shown in FIGS. 7 and 6). In some cases, a portion of the process 800 can be performed manually by an operator of the filter assembly.

At block 904 a filter can be inserted into a filter assembly (e.g., into a filter housing of a filter assembly) . . . . In some examples, inserting and securing a filter can include fastening a clamp to the filter and the filter housing to provide a seal therebetween (e.g., the filter 452 can be inserted into the filter housing 468, and the clamp 486 can secure the filter 452 to the housing 468 at flanges 494, 496).

At block 908 a filter integration process can be initiated. In some examples, the initiation of the integration process may include pressing a button, turning a knob, flipping a switch, entering a command, or any other input. For example, referring to FIG. 5, when a filter is inserted and secured in the housing 568, an operator can press the button 590. A controller (e.g., controller 696 shown in FIG. 6 or controller 708 shown in FIG. 7) can receive a signal when the button 590 is pressed, and can determine based on a state of the filter assembly (e.g., an inactive state of the flow line) that the signal indicates a filter integration.

At block 912 the process can include opening an upstream valve. Opening the upstream valve can allow a flow of fluid into a previously isolated flow line. With reference to FIG. 3, the upstream valve 360 can be opened at block 912 and fluid can begin to flow from the unified inlet 316 into the filter housing 358. In some examples, an upstream valve may be similar to any entry valves previously described. For example, with reference for FIG. 2, opening the upstream valve can include moving the three-way ball valve 258 to a position allowing flow into one or both of the flow lines 204, 208.

At block 916 the method can include filling and bleeding an air from all or a portion of filter assembly. For example, with reference to FIG. 3, when the valve 360 is opened, a fluid can flow through the valve 360 into the filter housing 358. When the exit valve 344 is closed, an air can be forced through the air bleed valve 362 as the fluid flowing into the filter housing displaces air previously in the housing 358.

At block 920, a time delay can be implemented before a downstream valve (e.g., exit valve 344 is opened) to allow fluid to flow through a portion of a filter assembly (e.g., the flow line 304 shown in FIG. 3). In some cases, a time delay setting can be stored in a control system of a filter assembly (e.g., in the memory 732 shown in FIG. 7). A time delay can allow a portion of a filter assembly to be filled, and can provide time for an air within the portion of the filter assembly to be bled from the filter assembly. In some cases, the time delay can be 30 seconds. In some cases, the time delay can up to 5 seconds, up to 10 seconds, up to 15 seconds, up to 20 seconds, or up to 25 seconds. In some cases, a time delay is a setting configurable by an operator of a filtration assembly. The process can continue filling the portion of the filter assembly while an elapsed time is less than the time delay. For example, with specific reference to FIG. 3, when the process 900 is implemented to fill the filter housing 358, the exit valve 344 can be in a closed position, preventing a flow of fluid from the unified entry 316 to the unified exit 312 through the first flow line 304. Thus, fluid can flow from the unified entry 316 into the filter housing 358 through the valve 360 (e.g., after the valve 360 is opened at block 912). As fluid flows into the filter housing 358 it can displace an air from the housing through the air bleed valve 362. The filling process can continue until a time has elapsed that is equal to or greater than the time delay (e.g., thirty seconds). The time delay can be selected to ensure that an air is evacuated from the filter housing 358 before a flow through the filter housing 358 to the unified exit 312 (e.g., to prevent the introduction of air bubbles into a liquid cooling system). In some cases, the time delay can be compared to a time since the upstream valve is opened at block 912.

At block 924, the process 900 can open a downstream valve of the filter assembly to allow flow through all or a portion of the filter assembly. For example, after a time elapsed exceeds a delay at block 920, a downstream valve of a flow line can be opened to allow fluid flow through the flow line. With reference to FIG. 3, for example, the process 900 can include opening the exit valve 344 after the time delay has elapsed, and fluid can flow from the unified inlet 316 to the unified outlet 312 through the flow line 304. In some cases, a downstream valve is not opened, and a flow line associated with the downstream valve can remain in an inactive state until receiving a failover signal.

At block 928 the process include includes providing an indication of integration. In some examples, an indication of integration may be provided via any output previously described. In other examples, indication of integration may be provided via visual indicators. For example, refereeing to FIG. 5, at block 924, when a fluid is flowing through the filter housing 568 (e.g., through the flow line associated with the filter housing 568), the visual indicator 94a can be activated (e.g., illuminated). In other examples, an indicator can be provided through a user interface (e.g., a touch-screen panel).

As noted above, in some cases, a filtration assembly can be operated in various modes, as can be best suited to system characteristics or to an operator's preference. For example, referring back to FIG. 6, the controller 696 can control configurations (e.g., positions) of the valves 640, 660, 644, 680 to implement given operating modes. FIG. 10 illustrates a flowchart showing a process 1000 for implementing operating modes of a filtration assembly (e.g., any or all of filtration assemblies 100, 200, 300, 600 shown in FIGS. 1, 2, 3, and 6). In some cases, a process for implementing operating modes of a filtration assembly can include more or fewer modes. Further, while blocks of the process 1000 are shown in a given order, the order is not limiting but the blocks of the process 1000 may be performed in other orders.

At block 1002, the process 1000 can include determining to run the filter assembly in dual filter mode or in a single filter mode. In some cases, a controller (e.g., controller 696 shown in FIG. 6, or controller 708 shown in FIG. 7) for a filter assembly can have stored thereon (e.g., at memory 732 shown in FIG. 7) a default setting for an operating mode, and determining a mode for the filtration assembly can include referencing the default (e.g., the factory setting). In some cases, an operator of the filtration assembly can select a mode in which to run the filtration assembly at an interface (e.g., a graphical user interface, an application programming interface, a command line interface, a control such as a button or knob along the filtration assembly, etc.).

At block 1004, if the selected mode is a dual filter mode, a controller of the filtration assembly can open first and second flow lines of the filtration assembly (e.g., flow lines 104, 108, 204, 208, 304, 308, 604, 608 shown in FIGS. 1, 2, 3, and 6). For example, with reference to FIG. 6, the controller 696 can issue signals to valves 640, 660 of the first flow line 604 to place the valves 640, 660 in an open configuration (e.g., position), allowing flow through the first flow line 604 (e.g., through the first filter 652). The controller can further provide signals to valves 644, 680 of the second flow line 608 to place the valves 644, 680 in an open configuration to allow flow through the second flow line 608 (e.g., through the second filter 672). In some cases, in dual filter mode, the controller 696 can maintain the valves 640, 660, 644, 680 in an open configuration until a signal is received to isolate one or both of the flow lines 604, 608. In some cases, an operator can implement a dual filter mode manually by engaging handles of valves of a filtration assembly to place the valves in an open configuration for both of a first and second flow line of a filtration assembly. Operating a filter assembly in dual filter mode can advantageously provide a lower pressure drop as compared to operating in a single filter mode, and can increase a run time of the filter assembly between servicing by providing for a substantially equal wear of components in each flow line of the filter assembly.

A filtration assembly operating in dual filter mode can maintain a flow through both a first flow line and a second flow line until a servicing signal is received for a filter of one of the first and second flow lines. For example, at block 1006, the process 1000 can determine if a servicing signal has been received. A servicing signal can be a signal initiated by an operator, or can be a signal based on a measured parameter of the filtration assembly. For example, a controller (e.g., controller 696 shown in FIG. 6) can receive a servicing signal when a user initiates a servicing of the filter 652 of the first flow line 604 by engaging a control of the first panel 688 (e.g., a user can push button 590 provided on the panel 588 shown in FIG. 5 to initiate a servicing), and in response, the controller can move the valves 640, 660 to a closed configuration to fluidly isolate the filter housing 648 and the filter 652 from the filter assembly 600. In some cases, a servicing signal can comprise a measurement from a differential pressure sensor that exceeds a pressure threshold. For example, with reference to FIG. 6, when a differential pressure measured by differential pressure sensor 620 exceeds a pressure threshold (e.g., a pressure threshold stored in the controller 696), a servicing signal can be generated at block 1006. In some cases, differential pressure sensors can be provided for each flow line of a filtration assembly, while in some cases, differential pressures can be calculated from sensed pressured along multiple points of the filtration assembly. While the discussion above has referenced a differential pressure, in some cases, other sense parameters can indicate a need for servicing, and an automated operation of a filtration assembly (e.g., process 1000) can receive or generate a servicing signal based on another sensed parameter. For example, a sensed flow rate, or a differential flow rate through one or both of a first and second flow line can indicate a need to service a filter of the respective flow lines. A servicing signal can comprise a communication received at a controller (e.g., a signal received from a button or other control), or can be generated at the controller based on sensed measurements. If no servicing signal is received at block 1006, the process 1000 can continue to implement block 1004 and can continue to allow a flow through the first and second flow lines.

At block 1008, in response to a servicing determination made at block 1006 (e.g., the reception of a servicing signal), a controller of a filtration assembly can close the flow line for which the servicing signal was received. For example, with reference to FIG. 6 the controller can isolate one or more flow lines 604, 608 (e.g., issue signals to entry and exit valves 640, 660, 644, 680) in response to a sensed parameter of the filter assembly 600. For example, the controller 696 can receive a pressure differential measurement from the differential pressure sensor 620 indicating a need to service filter 672 or the second flow line 608 (e.g., at block 1006), and when the pressure differential is greater than a pressure threshold, the controller can issue a signal to valves 644, 680 of the second flow line 608 to isolate the second flow line.

At block 1010, the process can determine if a servicing of a filter of a flow line has been completed. If the servicing has not completed, the controller can continue to prevent a flow of fluid through the flow line being serviced (e.g., by maintaining entry and exit valves of the flow line in a closed configuration). In some cases, determining if servicing has complete for a flow line can include one or both of receiving a pressure differential measurement from a differential pressure sensor of the flow line indicating that a differential pressure of the flow line is below a threshold pressure value, and receiving a user input indicating a servicing has been performed. For example, with reference to FIG. 5, when the filter 698 has been serviced and installed within filter housing 568, the user can engage the button 590 (e.g., can initiate the filter integration process at block 908 of process 900 shown in FIG. 9), and a signal from the button 590 can be received at a controller (e.g., controller 696, 708 shown in FIGS. 6 and 7) to indicate a servicing has been performed. In some cases, the process 1000 can require that a differential pressure (e.g., a differential pressure measured at differential pressure sensor 120, 220, 620, a differential pressure sensor for an individual flow line, etc.) be below a threshold pressure value before determining that a servicing is complete at block 1010. When the servicing is complete at block 1010, the process can proceed to open both of the first and second flow lines at block 1004. Reopening a flow line that has been serviced can include implementing all or a portion of the process 900 shown in FIG. 9.

If, at block 1002, the process determines (e.g., in response to a user input, a stored configuration, an algorithmic determination, etc.) to run the filtration assembly in a single filter mode, the process 100 can proceed to block 1011 to determine whether to operate the filtration assembly in static or dynamic mode. In some cases, the determination of blocks 1011 and 1002 can be performed simultaneously. For example, a user can select a mode of operation (e.g., from a drop-down, a radio button list, etc.) that can include one of a dual filter mode, a static single filter mode, and a dynamic single filter mode.

If at block 1011 the process 1000 determines to operate the filtration assembly in a dynamic single filter mode, the process can proceed to block 1012 and select a primary flow line. For example, with reference to FIG. 6, the controller 696 can select the first flow line 604 as the primary flow line, or can select the second flow line 608 as the primary flow line. In some cases, an initial primary flow line can be stored in one or more system configurations of the controller 696. For example, a parameter stored in the controller 696 (e.g., in the memory 732 of the controller 708 shown in FIG. 7) can set the first flow line 604 as an initial primary flow line. In some cases, a determination of an initial primary flow line can be made based on a sensed parameter of the filtration assembly (e.g., the primary flow line can be determined to be the flow line with a lower differential pressure measurement of both flow lines). In some cases, any selection method (e.g., random selection) can be used to determine an initial primary flow line at block 1012.

At block 1014, the process 1000 (e.g., the controller implementing the process 1000) can open the primary flow line and close the secondary flow line (e.g., the flow line not selected as the primary flow line). For example, with reference to FIG. 6, if the first flow line 604 is selected as the primary flow line at block 1012, the controller 696 can provide signals to open valves 640, 660 to allow flow through the first flow line 604 (e.g., through the filter 652) and can provide signals to close the valves 644, 680 to isolate the second flow line 608 (e.g., to prevent a flow of fluid through the second filter 672).

At block 1016, the process 100 can implement a wait period for a predetermined time interval. In some cases, for example, the time interval can be up to 1 minute, up to five minutes, up to 10 minutes, up to 20 minutes, up to 30 minutes, up to an hour, or greater than an hour. During the wait period, the filtration assembly can operate with the fluid flowing through the primary flow line, and the secondary flow line being isolated. In some cases, the wait can be initiated upon the initiation or completion of opening the primary flow line at block 1014.

At block 1018, after the predetermined time interval has passed (e.g., the primary flow line has operated continuously for the predetermined time interval), the process can switch the primary and secondary lines, and the flow line previously selected as the primary flow line can be designated as the secondary flow line. Switching the primary and secondary flow lines can include changing a parameter in a controller or a memory designating a given flow line as a primary or secondary. The process an proceed to block 1014 to open the flow line designated as the primary flow line at block 1018, and close the flow line designated as the secondary flow line at block 1018. For example, with reference to FIG. 6, the first flow line 604 can be the primary flow line and during the predetermined time interval, the valves 640, 660 can be open, and the valves 644, 680 can be closed. After the passage of the time interval, the controller can issue signals to close valves 640, 660, and open valves 644, 680, making the second flow line 608 the primary flow line, and making the first flow line 604 the secondary flow line. Thus, in a dynamic single filter mode, a controller of a filtration assembly can periodically and iteratively alternate between flow lines and corresponding filters of the filter assembly.

If, at block 1011, the process 100 determines to operate the filter assembly in a static single filter mode, the process 1000 can proceed to block 1020 and can select a primary flow line. 1020. In some cases, the primary flow line can be selected based on a configuration in a memory (e.g., memory 732 of controller 708 shown in FIG. 7). In some cases, a primary flow line can be selected based on a measured system parameter. For example, with reference to FIG. 6, the controller 696 can select the flow line 604 as a primary flow line based on a determination that a differential pressure along the first flow line 604 is lower than a differential pressure along the second flow line 608.

At block 1022, the process 1000 can open the primary flow line and close the secondary flow line. For example, with continued reference to FIG. 6, the controller can select the first flow line 604 as the first flow line at block 1020, and the second flow line 608 as the secondary flow line. The controller 696 can provide a signal to the valves 660, 640 to maintain the valves in an open configuration (e.g., to allow a flow of fluid through the first filter housing 648 and the first filter 652), and can provide a signal to the valves 644, 680 to isolate the second flow line 608.

At block 1024, the process can determine if a servicing signal has been received for the primary flow line (e.g., similar to block 1010). As discussed with respect to block 1010, a servicing signal can comprise a determination that a differential pressure for a flow line exceeds a threshold differential pressure value. In some cases, a servicing signal can be initiated by an operator (e.g., at button 590 of panel 588 shown in FIG. 5) additionally or alternatively.

At block 1026, if the servicing signal is received, the process 1000 can close the primary flow line and open the secondary flow line. For example. With reference to FIG. 6, when a pressure drop across the primary flow line 604 (e.g., as measured by the differential pressure sensor 620) exceeds a pressure threshold (e.g., a servicing threshold), the controller 696 can communicate with the valves 640, 660 to close the valves 640, 660 (e.g., isolating the first flow line) and can further communicate with valves 644, 680 of the second flow line 608 (e.g., the secondary flow line) to move the valves 644, 680 to an open configuration and allow flow through the second flow line (e.g., through the filter housing 688 and the filter 672).

The previous description of the disclosed embodiments is provided to enable any person skilled in the art to make or use the disclosure. Various modifications to these embodiments will be readily apparent to those skilled in the art, and the generic principles defined herein may be applied to other embodiments without departing from the spirit or scope of the disclosure. Thus, the disclosure is not intended to be limited to the embodiments shown herein but is to be accorded the widest scope consistent with the principles and novel features disclosed herein.

1. A filtration assembly for a liquid cooling system, comprising:
a fluid inlet;
a fluid outlet;
a first flow line positioned fluidly between the fluid inlet and the fluid outlet, the first flow line comprising a first canister filter, a first filter housing, and a first valve configured to move between a closed position and an open position, wherein, when the first valve is in the closed position a fluid flow through the first flow line is stopped;
a second flow line positioned fluidly between the fluid inlet and the fluid outlet, the second flow line including a second cannister filter and a second filter housing and a second valve configured to move between a closed position and an open position, wherein, when the second valve is in the closed position a fluid flow through the second flow line is stopped;
a differential pressure sensor;
a controller in communication with the differential pressure sensor and the first valve, the controller configured to:
receive, from the differential pressure sensor, a differential pressure value, and
when the differential pressure value is greater than a threshold value, generate a signal to one of the first and second valves to close the valve.

2. The filtration assembly of claim 1, wherein the first flow line further comprises a first air bleed valve, and the second flow line further comprises a second air bleed valve.

3. The filtration assembly of claim 1, wherein the first flow line include a first drain port.

4. The filtration assembly of claim 3, including a drain valve in fluid communication with the first drain port.

5. The filtration assembly of claim 1, wherein the first flow line further includes a third valve, wherein the third valve is downstream of the first canister filter and the first filter housing and the first valve is upstream of the first canister filter and the first filter housing.

6. The filtration assembly of claim 5, further comprising a control panel associated with the first flow line, the control panel including a first control in communication with the controller, wherein the controller is further configured to:
in response to a first signal received from the first control, provide a signal to move both of the first and third valves to a closed position.

7. The filtration assembly of claim 6, wherein the controller is further configured to:
receive a second signal from the first control;
in response to receiving the second signal:
provide an open signal to the first valve to move the first valve to the open position,
wait for a predetermined period of time after providing the open signal to the first valve,
after the predetermined period of time has elapsed, provide an open signal to the second valve to move the second valve to the open position.

8. The filtration assembly of claim 6, wherein the control panel include a first visual indicator, the first visual indicator configured to illuminate when the first valve and the third valve are in the open position.

9. The filtration assembly of claim 1, further comprising a second differential pressure sensor, wherein the differential pressure sensor is configured to measure a differential pressure along the first flow line, and wherein the second differential pressure sensor is configured to measure a differential pressure along the second flow line.

10. The filtration assembly of claim 1, wherein the first filter include a first air bleed valve.

11. A method of operating a filtration assembly including:
providing a unified fluid inlet and a unified fluid outlet;
providing a first flow line downstream of the unified fluid inlet and upstream of the unified fluid outlet, the first flow line including a first entry valve, a first exit valve, and a filter fluidly between the first entry valve and the first exit valve;
providing a second flow line downstream of the unified fluid inlet and upstream of the unified fluid outlet, the second flow line including a second entry valve, a second exit valve, and a second filter fluidly between the first entry valve and the first exit valve;
providing a differential pressure sensor, the differential pressure sensor configured to measure a differential pressure along the first flow line;
receiving a differential pressure measurement from the differential pressure sensor and, when the differential pressure measurement exceeds a pressure threshold, close the first entry valve and the first exit valve.

12. The method of claim 11, further comprising:
receiving a servicing signal indicating an initiation of a servicing for the first filter; and
in response to receiving the servicing signal, closing both of the first entry valve and the first exit valve.

13. The method of claim 12, further including providing a first control panel having a first button, wherein the servicing signal is generated upon a user engagement of the first button.

14. The method of claim 12, further comprising:
receiving an integration signal;
in response to receiving the integration signal, opening the first entry valve;
waiting for a predetermined time interval from the opening of the first entry valve;
bleeding an air from the first flow line; and
after the predetermined time interval, opening the first exit valve.

15. A filtration assembly comprising:
a fluid inlet;
a fluid outlet;
a first flow line, positioned fluidly downstream of the fluid inlet and upstream of the fluid outlet, the first flow line comprising a first entry valve, a first exit valve, a first drain port, a first filter housing, and a first filter, the first drain port, first filter housing, and first filter being downstream of the first entry valve and upstream of the first exit valve;
a second flow line, positioned fluidly downstream of the fluid inlet and upstream of the fluid outlet, the second flow line comprising a second entry valve, a second exit valve, a second drain port, a second filter housing, and a second filter, the second drain port, second filter housing, and second filter being downstream of the first entry valve and upstream of the first exit valve;
a differential pressure sensor;
and a controller in electrical communication with the first entry valve, first exit valve, second entry valve, second exit valve, the controller including a processor configured to:
receive, from the differential pressure sensor a differential pressure measurement of a differential pressure across the first flow line, and
when the differential pressure measurement exceeds a threshold value, issue a signal to the first entry valve and the first exit valve to close the first entry valve and the first exit valve.

16. The filtration assembly of claim 15, further comprising a first control panel having a first button and a first visual indicator, wherein the processor is further configured to:
receive a first signal indicative of an engagement of the first button,
in response to receiving the first signal, close the first entry valve and the first exit valve, activate the first visual indicator.

17. The filtration assembly of claim 16, wherein the first control panel includes a second visual indicator wherein the processor is further configured to:
receive, from the first button, a second signal;
open the first entry valve;
wait for a predetermined period of time after opening the first entry valve;
after waiting for the predetermined period of time, open the first exit valve;
deactivate the first visual indicator;
activate the second visual indicator.

18. The filtration assembly of claim 15, wherein the first filter includes a first air-bleed valve.

19. The filtration assembly of claim 15, wherein the first filter is secured to the first filter housing with a first clamp.

20. The filtration assembly of claim 16, wherein the first control panel is secured to the first filter housing.
